(19) United States
(12) Patent Application Publication
(10) Pub. No.: US 2026/0114183 A1
(43) Pub. Date: Apr. 23, 2026

(54) SEMICONDUCTOR HEAT MANAGEMENT

(71) Applicant: Kriisa United LLC, Hampshire, IL (US)

(72) Inventor: Arvo Palm-Leis, Decatur, IL (US)

(21) Appl. No.: 19/117,869

(22) PCT Filed: Aug. 31, 2023
(86) PCT No.: PCT/US2023/031674

§ 371 Date: Apr. 2, 2025

Related U.S. Application Data
(60) Provisional application No. 63/412,971, filed on Oct. 4, 2022.

(51) Int. Cl. H10N 19/00; H10N 10/81; H10W 40/50

(52) U.S. Cl. CPC H10N 19/00; H10N 10/81; H10W 40/50

(57) ABSTRACT

An apparatus and system are described to provide thermal management in electronic devices. An apparatus includes a substrate, a Kriisa current source disposed on the substrate, and a heat source to which the Kriisa current source is thermally and electrically coupled to provide cooling of the heat source simultaneously with current to the heat source or a separate load.

### PRIORITY CLAIM

This application claims the benefit of priority to U.S. Provisional Patent Application Ser. No. 63/412,971, filed Oct. 4, 2022, which is incorporated herein by reference in its entirety.

### TECHNICAL FIELD

Embodiments pertain to heat management in semiconductor integrated circuits.

### BACKGROUND

Integrated circuits are the lifeblood of modern society. The continuous desire for increasing advanced functions and speed of electronic devices have led to an ever-increasing complexity and density of the integrated circuits that provide the functionality and speed. The individual components that form an integrated circuit, including transconductance devices (e.g., transistors), resistors, and other discrete components, generate heat in proportion to the current flowing through the component and resistance of the component.

Heat dissipation, which affects device performance, and heat-related issues have only been exacerbated with the increasing number of substrate layers and component density. The heat generated by the components is typically managed via external cooling through routing the heat to a heat-dissipation element outside of the circuit. In fact, in many cases the device performance is limited by thermal management of the components and structures in an integrated circuit. Accordingly, it would be desirable to improve thermal management in electronic devices, and in particular integrated circuit structures.

### BRIEF DESCRIPTION OF THE FIGURES

In the figures, which are not necessarily drawn to scale, like numerals may describe similar components in different views. Like numerals having different letter suffixes may represent different instances of similar components. The figures illustrate generally, by way of example, but not by way of limitation, various embodiments discussed in the present document.

FIG. 1 illustrates a Kriisa current source in accordance with some embodiments.

FIG. 2 illustrates a Kriisa current source on a substrate in accordance with some embodiments.

FIG. 3 illustrates a Kriisa current device as an intervening layer between a substrate and heat source in accordance with some embodiments.

FIG. 4 illustrates a Kriisa current device disposed on a heat source that is fabricated on a substrate in accordance with some embodiments.

FIG. 5 illustrates a substrate layer intervening between a Kriisa current source and a heat source in accordance with some embodiments.

FIG. 6 illustrates the heat source as an intervening layer between two Kriisa current sources, all on a substrate in accordance with some embodiments.

FIG. 7 illustrates a block diagram of an apparatus in accordance with some embodiments.

FIG. 8 illustrates a method of fabricating a Kriisa apparatus in accordance with some embodiments.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

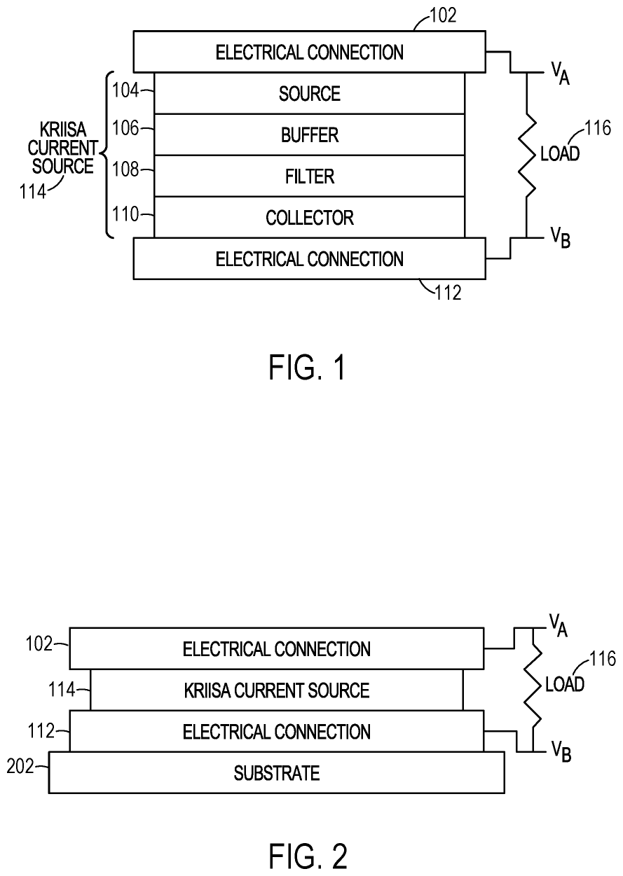

FIG. 1 illustrates a Kriisa current source with electrical connections for the generated current to an electrical load. Referring to FIG. 1, the Kriisa current source 114 includes a source 104, a buffer 106, a filter 108, and a collector 110. Each of the layers of the Kriisa current source 114 may be, for example, an epitaxial layer that physically and electrically contacts at least one other layer of the Kriisa current source 114; that is, as shown in FIG. 1, the source 104 contacts the buffer 106, the buffer 106 contacts the filter 108 (and the source 104), and the filter 108 contacts the collector 110 (and the filter 108). The source 104 and the collector 110 are also respectively connected to an electrical connection 102, 112. Leads from which current may be extracted from the Kriisa current source 114 are electrically connected to the source 104 and the collector 110 through the respective electrical connection 102, 112. A magnetic field may be applied in a direction substantially perpendicular (e.g., within about five degrees of normal) to the layers 104, 106, 108, 110 of the Kriisa current source 114 via a magnetic source. The magnetic source may be a coil or other device able to provide a controllable magnetic field to the Kriisa current source 114. The electrical connections 102, 112 may be or include, for example, conductive routing disposed on or formed in an epitaxial layer.

Although the layers 104, 106, 108, 110 of the Kriisa current source 114 are shown as single layers, one or more of the layers 104, 106, 108, 110 may include additional layers. In some embodiments, one or more of the layers 104, 106, 108, 110 may have multiple layers formed from the same or different materials that provide the same overall characteristics as a single layer structure. Similarly, the multiple layers may have the same thickness or different thicknesses (within formation tolerance). The interaction of the source 104, buffer 106, filter 108, and collector 110 produces a spontaneous current. The movement of charge across the Kriisa current source 114 produces a voltage, which rises until a balancing reverse current appears. If a load 116 is connected to the Kriisa current source 114 through the leads, current flows through the load 116 and power is dissipated. The energy for originates from the thermal energy in the Kriisa current source 114, causing the Kriisa current source 114 to cool.

The source 104 may be a metal or mixture of metals that has localized states at or near the bottom of the conduction band. In some embodiments, the states may have an energy between about 0.01 eV and about 0.05 eV below the bottom of the conduction band. The number of these states may be low enough so that their overlap is small and the levels are not degenerate (i.e., the levels do not spread into an impurity band that merges with the conduction band). In one embodiment, the concentrations are less than about 1000 ppm (part per million).

Interactions between electrons near the Fermi surface and the localized electrons trapped on the localized states may elevate the localized electrons to the Fermi surface. The energy for this transition may be between about 1 and 6 eV, dependent on the metal (single metal or mixture of metals), and may arise from the energy of collisions of the localized electron with multiple free electrons. Normal collisions return an electron to the localized state and produce excess electrons above the Fermi surface and excess holes below. Movement of these energetic electrons and holes may be the source of the current. Interactions between localized electrons and phonons can also elevate the localized electrons to the Fermi surface. In this case, the energy for the transition may originate from multiple phonons.

The probability of transition of the localized electrons to the Fermi surface, which occurs in the source, may be large enough to produce enough energetic electrons. The localized states in the metal may be produced in multiple ways, including disorder in the metal (a metal whose potential for conduction electrons is non-periodic), small amounts of impurities, and/or an applied magnetic field.

Disorder may arise from the use of an alloy of two or more metals whose atoms are randomly distributed throughout the lattice. Note that a pure metal may consist of more than one stable isotope that may be randomly distributed throughout the lattice, producing a slightly disordered potential. The metal may be in a metastable mixture of two different crystal forms, in a structure called random stacking. Or the metal may be a transition metal with localized magnetic moments pointing in random directions. The non-periodic potential may produce localized states at the bottom of the conduction band through the process of Anderson localization. Disordered metals can be divided into two classes, pure metals and mixtures.

Transition metals have randomly oriented magnetic moments due to the incomplete filling of the d shell. The random orientation of the magnetic moments of these shells may produce a disordered potential for the conduction electrons in these metals. In particular, the potential that a conduction electron experiences while on an atom may depend on the relative orientations of the magnetic moments of the atom and its nearest neighbors. Most of the transition metals have crystal structures in which every atom has 12 nearest neighbors. Most of the remaining transition metals have structures with 8 nearest neighbors. It may be that, for an atom to have a low enough potential to produce a localized state with an energy of about 0.01 eV below the bottom of the conduction band, 9 of its nearest neighbors have magnetic moments aligned with its magnetic moment, and 3 are anti-aligned with its magnetic moment. With randomly aligned moments, the fraction of atoms with localized states may be low enough to satisfy the above conditions.

The normal situation is more complicated, because most d shells have more than two possible orientations, (j>½, where j is the angular momentum quantum number), but the same principle may apply. In ferromagnetic metals Fe, Co, and Ni, the relative orientations of neighboring magnetic moments are not random for T<T_{c} (the Curie temperature). At T=0, all the magnetic moments are aligned and the atom does not have a lower potential than the average. As temperature is increased, disorder increases until at some temperature some atoms may have localized states; the number of localized states increasing with increasing temperature.

In mixtures of two or more metals, the random positions of the different atoms may produce a disordered potential. Mixtures may include metals that normally dissolve in each other, such as Ni—Cu, Pd—Ag, Pt—Au, or of metals that do not normally mix but can be deposited in a mixed state. Examples of metals that do not normally mix include Fe—Co and Ti—V.

The use of impurities whose size is significantly different from the size of the host metal atoms may also result in localized states. For non-transition metals, the impurity metal may be of the same column of the periodic table as the parent metal, and usually lower in the column. For instance, Ga or In may be used as impurities in Al, or K or Rb may be used as impurities in Na. However, there are also exceptions to these rules; for instance, Bi impurities in Pb produce localized states. For transition metals, the impurity metal can be of the same column as the parent metal or may be of a column to the right of the column of the parent metal. Cu in Ni is one such example.

The concentration of the impurity atoms can range from less than 1 ppm up to an upper limit in which the isolated localized states overlap and merge to become the disordered localized states. For low concentrations (<1000 ppm), the number of energetic electrons produced is proportional to the concentration of impurities.

In addition to, or instead of, use of a disordered structure and/or impurities, an external magnetic field can be applied to produce the current source. If a magnetic field is applied to a metal, states that are localized in two dimensions, called Landau states, are produced at the bottom of the conduction band. To produce the Landau states, the metal is substantially free of disorder (e.g., a non-transition metal may have a purity greater than about 99.9%).

In non-transition metals, excitation of an electron from a localized state at the bottom of the conduction band to the Fermi surface may be generated close to the physical surface of the metal (e.g., within about 100 Å) by the application of an alternating electric field and/or a non-parallel magnetic field in transition metals; in transition metals, the excitation may be a result of the interaction of the incomplete d-shells of neighboring atoms and thermal vibrations (phonons) of the atomic lattice. This excitation may be increased with particularized selection of metals used.

One way to apply the electric field is to select a material that has a high density of optically active localized phonon modes as the neighboring layer or layers (i.e., the buffer layer 106 and/or the filter layer 108). The material thus has a large number of charged atoms that are vibrating, producing an alternating electric field. This alternating electric field is able to penetrate a short distance into the source 104. Typical frequencies of vibration of the charged atoms extend between about 1012 to 1013 Hz. For a vibration frequency of about 1013 Hz, for example, Cu has a skin depth of 200 Å. For other metals, the depth may be different.

As above, a magnetic field may be applied externally. In different embodiments, the magnetic field can be applied by placing a current source in a solenoid or by placing permanent magnets nearby. The output of the source can then be controlled by changing the strength of the applied magnetic field. Alternately, or in addition, the temperature of the Kriisa current source 114 may be increased.

The thickness of the source 104 can vary from few atomic thicknesses (about 10 Å). For thicknesses below about 100 Å, a buffer may be used on one or both sides of the source 104.

The buffer 106 permits the excitation processes in the source 104 to occur close enough to the surface of the source 104 so that an appreciable fraction of the excess electrons and excess holes far from the Fermi energy reach the surface of the source 104. In this case, the bottom of the conduction band in the source 104, where the localized states are disposed, lines up with a forbidden band of the buffer 106. A suitable buffer 106 may be a metal, insulator or semiconductor. The buffer 106 may be thin enough (about 10-50 Å) so that a substantial fraction of the energetic charges (electrons or holes) pass through to the filter 108. For example, if the buffer 106 is an insulator, the charges from the source 104 may tunnel through the buffer 106 to the filter 108.

The filter 108 functions to conduct the high energy charges originating from the source 104 and to block the flow of electrons close to the Fermi surface. In one embodiment, the filter 108 comprises a semiconductor, such as Si or Ge or a compound (e.g., binary, ternary, quaternary) semiconductor semiconductor formed from one or more elements from column III, IV, V, and/or VI of the periodic table. Alternatively, the filter 108 may comprise an insulator such as SiO₂, CaO, or AlN. In various embodiments, the filter 108 may conduct high energy electrons and/or holes while blocking other charge carriers.

The collector 110 may be a metal or a heavily doped semiconductor (e.g., about 10¹⁷ cm⁻³ or more dopants) and can be any thickness above about 10 Å. An outside electrical connection to the collector 110 may be at least about 1 micron thick. The collector 110 may be selected to make an ohmic contact with the semiconductor filter 108 in some cases, and in other cases to make a rectifying contact. The choice of collector metal in this case can be based on compatibility with neighboring layers. Sn, for example, may be a good choice.

Excitation processes in the source metal cause there to be more electrons and holes far from the Fermi energy than what is predicted by equilibrium statistical mechanics. The buffer 106 allows those energetic charges to reach the surface of the source 104 and to pass into and through the buffer 106, into the filter 108. The filter 108 allows some of the high energy charges to pass through into the collector 110. The collector 110 does not have a surplus of high energy charges that are able to pass through the filter 108. Consequently, charge builds up in the collector 110 and an electric field develops in the filter 108. The field grows until a balancing current flowing in the opposite direction develops. If the field grows too large, breakdown will occur in the semiconductor, destroying its ability to filter. In addition, the filter 108 and collector 110 permit sufficient reverse current to flow so that breakdown does not occur. This can be done in a number of ways. If the semiconductor is thin enough (about 50 Å), tunneling can occur from the collector 110 to the buffer 106 or source 104. If the semiconductor has enough defects, such as amorphous silicon or germanium, conduction through defect states in the middle of the forbidden band can occur. If the collector metal forms an ohmic contact with the filter layer semiconductor, a Schottky diode is formed. As charge builds up in the collector, the Schottky diode becomes forward biased in the collector-source direction and a balancing reverse current can develop.

If the semiconductor in the filter 108 is undoped, thus having an intrinsically high resistance, the thickness of the filter 108 is limited to about 100 to 200 Å to prevent space-charge effects, which will produce instabilities in output current. If the semiconductor is doped or low resistance, the thickness can be above about 100 Å.

Semiconductors used may include, for example, Si, Ge, GaAs, AlAs, AlSb, SnO₂, among many others. Insulators that can be used include MgO and CaO. If the semiconductor also provides probability amplification as previously discussed, it has a large number of localized phonon modes. Other semiconductors include, such as AlₓGa₁₋ₓAs or AlAsₓSb₁₋ₓ or ZnOₓS₁₋ₓ, where x can vary from about 0.25 to 0.75. These mixtures are good semiconductors but have a disordered phonon spectrum with many localized modes. Those modes provide an alternating electric field, which when combined with an externally applied magnetic field provides amplification in the source. More complicated semiconductors such as organic semiconductors also can be used.

The layers of the Kriisa current source 114 may be fabricated by a number of techniques, such as vacuum deposition. Different vacuum deposition technologies may be suitable for fabrication of the current source 100. These vacuum deposition technologies include sputtering, chemical vapor deposition, and electron beam evaporation. Further specifics of materials forming the layers, as well as the fabrication techniques may be found in U.S. Pat. Nos. 8,053,942 and 8,581,469, which are herein incorporated by reference in their entirety.

The layers of the Kriisa current source 114 may be fabricated by any of a variety of thin film fabrication techniques. The localized and free electrons in the source layer 104 interact, resulting in energized electrons with energy above the Fermi surface. The buffer layer 106 allows energetic electrons to reach the filter 108. The energetic electrons may then migrate to the collector 110. The charge movement may result in a potential between the electrical connections 102. Electrical connections 102 interface the Kriisa current source 114 with a load 116. Various configurations and methodologies can be used to build the Kriisa current source 114 current source.

FIG. 2 illustrates a Kriisa current source on a substrate. The arrangement in FIG. 2 is similar to that of FIG. 1, with the Kriisa current source 114 providing current to a load 116 via electrical connections 102. In FIG. 2, however, the Kriisa current source 114 and electrical connections 102, 112 are disposed on a substrate 202. The substrate 202 may be formed from a transparent material, such as glass, or an opaque material, such as a semiconductor or insulator such as sapphire. The substrate 202 may be used to mount integrated circuits, or on which integrated circuits are fabricated or otherwise attached. A heat source, as described in more detail below, may be disposed on the substrate 202. The layers shown may be expitaxial layers formed on (grown and fabricated) or transferred to (after growth and fabrication) the substrate 202. Although not shown, the substrate 202 may be provided in each embodiment described herein.

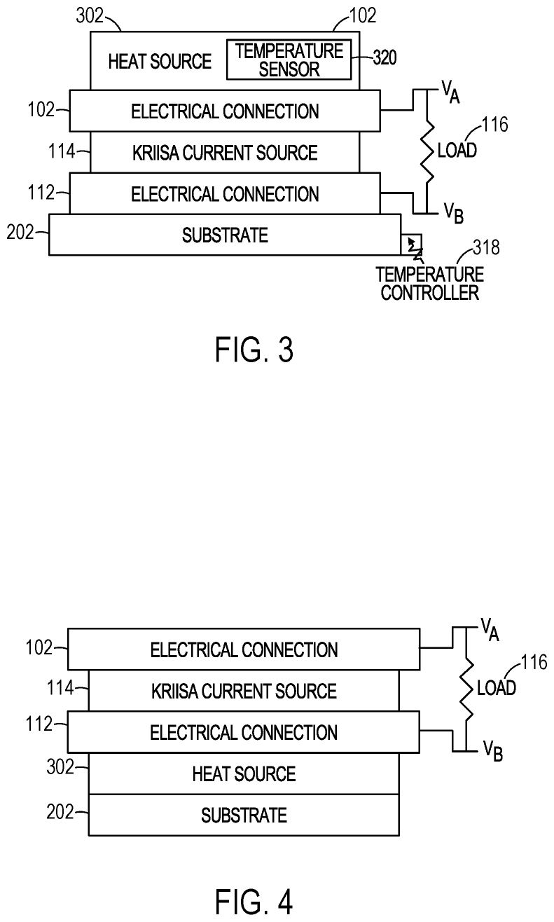

FIG. 3 illustrates a Kriisa current device as an intervening layer between a substrate and heat source. The arrangement in FIG. 3 is similar to that of FIG. 2, with the Kriisa current source 114 providing current to a load 116 via electrical connections 102. In FIG. 3, the Kriisa current source 114 and electrical connections 102, 112 are disposed on a substrate 202, such as that above. In addition, a heat source 302 is disposed on one of the electrical connections 102, 112. As shown in FIG. 3, the heat source 302 is disposed on the electrical connection 102 (also referred to as the first electrical connection 102) that is on an opposite side of the Kriisa current source 114 than the substrate 202. Specifically, the heat source 302 is disposed on an opposite side of the first electrical connection 102 than the Kriisa current source 114. In some embodiments, other conductive layers may be disposed between the heat source 302 and the first electrical connection 102. The heat source 302 may thermally and/or or electrically contact the first electrical connection 102, either directly or through one or more intermediate layers such the other conductive layers or non-conductive layers by vias. The heat source 302 may be a semiconductor device (e.g., integrated circuit) that generates heat when a current is supplied thereto, e.g., through direct connections thereto. The heat source 302 may be fabricated using similar techniques as the other layers of the Kriisa current source 114. The heat source 302 may supply heat to the Kriisa current source 114 to increase the transition probability of the localized electrons to the Fermi surface as described herein and in the related patents without detrimentally affecting other properties of the structure shown in FIG. 3.

FIG. 4 illustrates a Kriisa current device disposed on a heat source that is fabricated on a substrate. The arrangement in FIG. 4 is similar to that of FIG. 3, excepting that the heat source 302 is disposed on the other of the electrical connections 112. That is, as shown in FIG. 4, the heat source 302 is disposed on the electrical connection 112, which is on the same side of the Kriisa current source 114 as the substrate 202 (also referred to as the second electrical connection 102). The heat source 302 is thus disposed between the electrical connection 112 and the substrate 202. The heat source 302 may thermally and/or or electrically contact the electrical connection 112, either directly or through one or more intermediate layers such the other conductive layers or non-conductive layers by vias. The heat source 302 shown in FIG. 4 may be the same as that shown in FIG. 3.

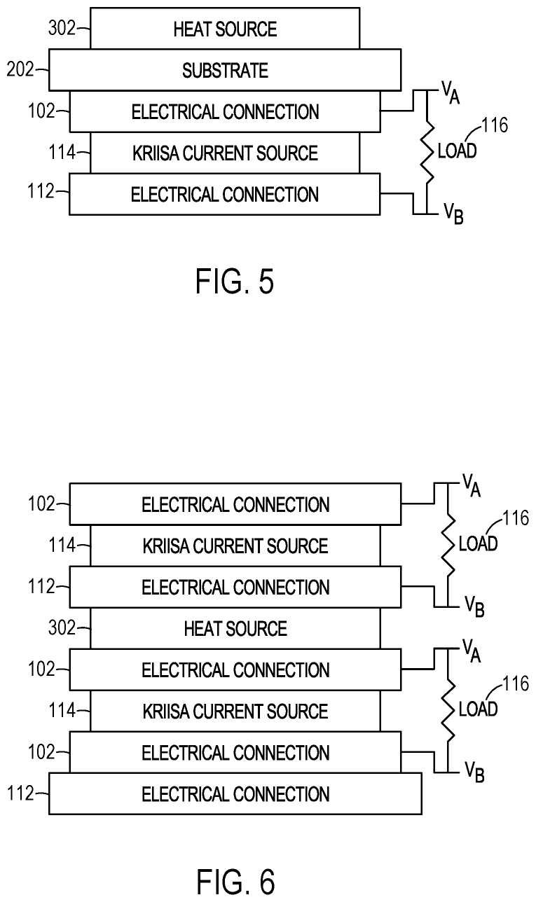

FIG. 5 illustrates a substrate layer intervening between a Kriisa current source and a heat source. The arrangement in FIG. 5 is similar to that of FIG. 4, excepting that the heat source 302 is disposed on the opposite side of the substrate 202 than in FIG. 4. That is, as shown in FIG. 4, the heat source 302 is disposed on the electrical connection 102 that is on the same side of the Kriisa current source 114 as the substrate 202, but the substrate 202 is disposed between the heat source 302 and the other electrical connection 112. The heat source 302 may thermally and/or or electrically contact the substrate 202, either directly or through one or more intermediate layers such the other conductive layers or non-conductive layers by vias. In other embodiments, a heat source 302 may be disposed on both sides of the substrate 202. The heat source 302 shown in FIG. 5 may be the same as that shown in FIG. 3.

FIG. 6 illustrates the heat source as an intervening layer between two Kriisa current sources, all on a substrate 202. The arrangement of FIG. 6 thus combines the arrangement of FIG. 3 with FIG. 2 (without the additional substrate of FIG. 2/3). That is the arrangement of FIG. 2 without the substrate 202 may be disposed on the arrangement of FIG. 3. The different Kriisa current sources 114 may provide current to different loads 116 or to the same load 116. The heat source 302 shown in FIG. 6 may be the same as that shown in FIG. 3.

As described, the Kriisa current source 114 in all of the above figures cools as power is dissipated in the connected load 116. The thermal energy removed from the Kriisa current source 114 may thus be equivalent to the energy dissipated in the load 116 (or nearly so).

As above, many integrated circuits, from simple voltage regulators and operational amplifiers to complex computer and video processors are built on semiconductor substates using semiconductor layers. In general, integrated circuits and other devices are mounted on thermal management components to provide heat conduction from the components. Thermal management in electronic devices and components therein (including integrated circuits) is an important aspect of the electronic devices and systems in which the electronic devices are incorporated due to the performance degradation and eventual breakdown at higher temperatures. For example, under normal operating conditions, it may be desirable for the temperature of processors used typical electronic devices to be less than about 90° C. (considered hot); a temperature that exceeds 110° C. is indicative that the processor is overheating and is detrimental to both short-term operation of the processor by reducing characteristics of the semiconductor and long-term operation of the processor as inhomogeneities and other physical damage occurs in the various layers. In addition, it may be desirable for the temperature of processors used typical electronic devices to be maintained within a limited range of temperatures, for example, commercial integrated circuits may have a desired range of about 0° to about 70° C. (with ideal CPU temperature range being between about 40° C. to about 65° C. for normal workloads, about 65° C. to about 70° C. when running essential applications, and about 70° C. to about 80° C. when running more intensive applications or games), while industrial-grade integrated circuits may have a range of about −45° C. to about 85° C., and military-grade integrated circuits may have a range of about −55° C. to about 125° C. The operating temperature ranges may depend on the semiconductor materials used, in addition to the application.

A typical personal computer processor includes several internal features for managing the heat output of the electrical activities in the package. The processor also uses external thermal management hardware to transport heat away. All of these add cost and complexity to the system, such as by the addition of cooling components, such as fans and heat sinks (e.g., fins). For example, the processor package may include several discrete semiconductor integrated circuit dies mounted on a common thermally conductive substrate. Each die may have one or more thermal sensors (also referred to as temperature sensors). The sensors may use a thermocouple or other temperature-sensitive device (e.g., measuring the temperature-dependent voltage drop across a forward-biased p-n junction or the variation in voltage across a diode junction) or may use infrared emissions to determine the temperature of the heat source (die). Those sensors are read, and the sensor data communicated to the processor level thermal management firmware or software, as well as communicated externally to the operating system or lower-level software to adjust operational parameters, such as clock speed or number of active cores, to maintain temperatures in the process within allowable limits stored in memory. External processes such as cooling fan speeds may also be continuously adjusted based on the sensor data. Those adjustments in operations parameters generally limit the workload of the processor based on thermal considerations. Throughput of the processor may be throttled, or in extreme conditions, the processor may be shut down.

The above examples rely on controlling temperature by moving heat by conduction from the source until the heat is reduced to a level within the desired range. The heat extraction typically occurs by convection into the environment. Exotic heat extraction materials, for example, diamond have been developed as materials with improved thermal conductivity over the more typical Al and Cu. Heat pipes that take advantage of the latent energy of phase changes of a medium also conduct heat. In any case, present thermal management strategies rely on a negative temperature gradient between the heat source and the heat dump.

Some electronic devices, such as infrared sensors, may reliably operate at operating temperatures below ambient (room) temperature. A temperature gradient to the desired operating temperature is not available. In this case, an active cooling arrangement, e.g., Peltier plates, can be used to lower the temperature of the electronic device. The operation of such devices, however, uses additional energy from the power supply of the system, as well as introducing additional complexity and cost.

To overcome these issues, the cooling property of the Kriisa current source 114 may be leveraged to convert thermal energy to electrical energy. For example, referring to FIG. 3, the Kriisa current source 114 may be fabricated on a substrate 202. The heat source 302 is an electronic device such as an integrated circuit that produces heat during operation, or an electronic device that for which a lower-than-ambient operating temperature is desirable, or a similarly thermally managed electronic device. The heat source 302 may be fabricated on the Kriisa current source 114. The Kriisa current source 114 may generate a potential differential across the electrical connections 102, 112. The current flows through a load 116, removing heat from the Kriisa current source 114. The Kriisa current source 114 is then at a lower temperature than the heat source 302, which causes heat to flow from the heat source 302 to the Kriisa current source 114, cooling the heat source 302 without (or perhaps in addition to) the use of convection or a heat dump. The heat flow may be essentially equal to the electrical power of the Kriisa current source 114. The electrical current produced by the Kriisa current source 114 may then be electrically conducted through the electrical connections 102, 112 to the load 116.

The embodiments of FIGS. 4-6, although having different arrangements, may operate in a similar manner. The embodiment of FIG. 6 illustrates a heat source 302 situated between two Kriisa current sources 114, which would allow twice the amount of heat removal from the heat source 302 as the embodiments of FIGS. 3-5.

In any of the embodiments, the load 116 can be passive (such as a resistor or capacitor), reactive (such as a motor or transformer), or active (such as a transistor). The load 116 may be one or more devices or other circuitry, such as light emitting devices, sensors, and the like. An active load may also include features to manage the temperature of the heat source 302. The temperature of the Kriisa current source 114 may be manipulated to maintain heat flow from the heat source into the Kriisa current source 114. Since the thermal flow out of the Kriisa current source 114 may be proportional to the current output, current controls can be implemented to manage the current flow of the Kriisa current source 114. The current controls may be local or remote and automatic (e.g., computer controlled) or manual (e.g., set by a user using local or remote inputs to limit the temperature range, remote inputs being connected, e.g., wirelessly to the temperature controller 318). The current controls may control the heat source 302 to be cooled to specific operating temperatures, as in the case of below-ambient-temperature infrared sensors. The current controls may be used to allow the heat source 302 to avoid problematic temperatures, such as humidity condensation dew points. The temperature controller may, for example, control one or more switches between the Kriisa current source 114 and the load 116 to control an amount of cooling provided to the heat source 302 by the Kriisa current source 114 and thus allow the temperature of the heat source 302 to be limited to a predetermined range by the Kriisa current source 114.

An active load can include systems that scavenge electrical energy by electrical energy harvesting technology. This electrical energy may then be used to supplement power to the device of the heat source 302. The harvested electrical energy may also be provided for other uses in the overall system that contains the Kriisa current source 114. Alternatively, or in addition, the harvested electrical energy may be stored in external storage devices such as capacitors or batteries. Other load types may include conversion to another form of energy, e.g., kinetic or radiative.

In some cases, additional thermal management may or may not be used for a continuous negative temperature gradient between the Kriisa current source 114 and the heat dump. As noted above, intervening layers, such as ground planes and dielectrics, are omitted from the figures for simplicity.

Depending on the band structure of the components of the Kriisa current source 114, a typical voltage at the electrical connections of a single source 104/buffer 106/filter 108/collector 110 structure may be about 0.1-0.5 V. The source 104/buffer 106/filter 108/collector 110 structure can be repeated any number of times in a Kriisa current source 114, which multiplies the potential at the electrical connections 102 by the number of repetitions. Output voltages of about 3-5 V can be nominal. The Kriisa current source 114 is capable of currents exceeding 50 A/cm². A typical computer processor chip heat source 302 is approximately 3 cm×3 cm; the embodiments of the Kriisa current source 114 may have a similar footprint of about 9 cm². Thus, the cooling capacity of such a Kriisa current source 114 is estimated to exceed about 4 V×50 A/cm²×9 cm²=about 1800 W. This is more than an order of magnitude greater than the capacity of 165 W specified for the heat management system of such a processor heat source 302.

In the embodiments above, a controller (not shown) may be used to control the supply of current to the load and/or cooling of the heat source. In such embodiments, the current from the Kriisa current source may be stored (e.g., in a capacitor) until a sufficient amount of power has been built up to drive the load. Sensors 320 may be used to control current to the load to provide a constant source of current. Such sensors 320 may include heat sensors to sense the temperature of the heat source (and thus amount of current generated), among others. In some embodiments, a table (or other conversion mechanism) of heat generated by the heat source to current generated by the Kriisa current source may be generated during a calibration period prior to operation. The conversion mechanism may be stored in memory.

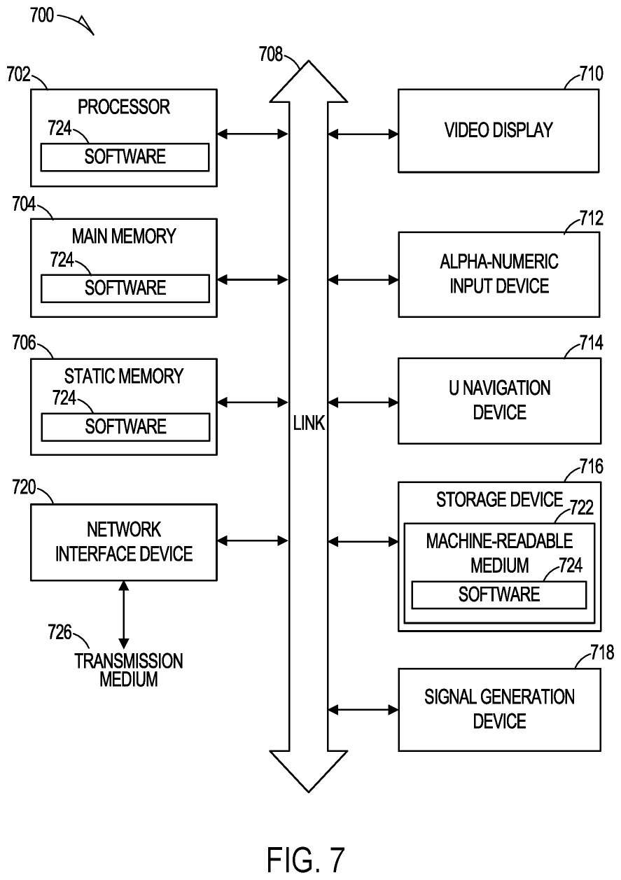

FIG. 7 illustrates a block diagram of an apparatus in accordance with some embodiments. The apparatus 700 (or various components thereof) may be or contain the load and/or the heat source. The apparatus 700 may be, for example, an electronic device such as a personal or laptop computer (PC), a tablet, or a smart phone, specialized equipment, a virtual device, or any machine capable of executing instructions (sequential or otherwise) that specify actions to be taken by that machine. Examples, as described herein, may include, or may operate on, logic or a number of components, modules, or mechanisms. Modules and components are tangible entities (e.g., hardware) capable of performing specified operations and may be configured or arranged in a certain manner. In an example, circuits may be arranged (e.g., internally or with respect to external entities such as other circuits) in a specified manner as a module. In an example, the whole or part of one or more computer systems (e.g., a standalone, client or server computer system) or one or more hardware processors may be configured by firmware or software (e.g., instructions, an application portion, or an application) as a module that operates to perform specified operations. In an example, the software may reside on a machine readable medium. In an example, the software, when executed by the underlying hardware of the module, causes the hardware to perform the specified operations.

Accordingly, the term “module” (and “component”) is understood to encompass a tangible entity, be that an entity that is physically constructed, specifically configured (e.g., hardwired), or temporarily (e.g., transitorily) configured (e.g., programmed) to operate in a specified manner or to perform part or all of any operation described herein. Considering examples in which modules are temporarily configured, each of the modules need not be instantiated at any one moment in time. For example, where the modules comprise a general-purpose hardware processor configured using software, the general-purpose hardware processor may be configured as respective different modules at different times. Software may accordingly configure a hardware processor, for example, to constitute a particular module at one instance of time and to constitute a different module at a different instance of time.

The apparatus 700 may include a hardware processor (or equivalently processing circuitry) 702 (e.g., a central processing unit (CPU), a GPU, a hardware processor core, or any combination thereof), a main memory 704 and a static memory 706, some or all of which may communicate with each other via an interlink (e.g., bus) 708. The main memory 704 may contain any or all of removable storage and non-removable storage, volatile memory or non-volatile memory. The apparatus 700 may further include a display unit 710 such as a video display, an alphanumeric input device 712 (e.g., a keyboard), and a user interface (UI) navigation device 714 (e.g., a mouse). In an example, the display unit 710, input device 712 and UI navigation device 714 may be a touch screen display. The apparatus 700 may additionally include a storage device (e.g., drive unit) 716, a signal generation device 718 (e.g., a speaker), a network interface device 720, and one or more sensors, such as a global positioning system (GPS) sensor, compass, accelerometer, or other sensor. The apparatus 700 may further include an output controller, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The storage device 716 may include a non-transitory machine readable medium 722 (hereinafter simply referred to as machine readable medium) on which is stored one or more sets of data structures or instructions 724 (e.g., software) embodying or utilized by any one or more of the techniques or functions described herein. The instructions 724 may also reside, completely or at least partially, within the main memory 704, within static memory 706, and/or within the hardware processor 702 during execution thereof by the apparatus 700. While the machine readable medium 722 is illustrated as a single medium, the term “machine readable medium” may include a single medium or multiple media (e.g., a centralized or distributed database, and/or associated caches and servers) configured to store the one or more instructions 724.

The term “machine readable medium” may include any medium that is capable of storing, encoding, or carrying instructions for execution by the apparatus 700 and that cause the apparatus 700 to perform any one or more of the techniques of the present disclosure, or that is capable of storing, encoding or carrying data structures used by or associated with such instructions. Non-limiting machine readable medium examples may include solid-state memories, and optical and magnetic media. Specific examples of machine readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; Random Access Memory (RAM); and CD-ROM and DVD-ROM disks.

The instructions 724 may further be transmitted or received over a communications network using a transmission medium 726 via the network interface device 720 utilizing any one of a number of wireless local area network (WLAN) transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks. Communications over the networks may include one or more different protocols, such as Institute of Electrical and Electronics Engineers (IEEE) 802.11 family of standards known as Wi-Fi, IEEE 802.16 family of standards known as WiMax, IEEE 802.15.4 family of standards, a Long Term Evolution (LTE) family of standards, a Universal Mobile Telecommunications System (UMTS) family of standards, peer-to-peer (P2P) networks, a next generation (NG)/5^{th} generation (5G) standards among others. In an example, the network interface device 720 may include one or more physical jacks (e.g., Ethernet, coaxial, or phone jacks) or one or more antennas to connect to the transmission medium 726.

Note that the term “circuitry” as used herein refers to, is part of, or includes hardware components such as an electronic circuit, a logic circuit, a processor (shared, dedicated, or group) and/or memory (shared, dedicated, or group), an Application Specific Integrated Circuit (ASIC), a field-programmable device (FPD) (e.g., a field-programmable gate array (FPGA), a programmable logic device (PLD), a complex PLD (CPLD), a high-capacity PLD (HCPLD), a structured ASIC, or a programmable SoC), digital signal processors (DSPs), etc., that are configured to provide the described functionality. In some embodiments, the circuitry may execute one or more software or firmware programs to provide at least some of the described functionality. The term “circuitry” may also refer to a combination of one or more hardware elements (or a combination of circuits used in an electrical or electronic system) with the program code used to carry out the functionality of that program code. In these embodiments, the combination of hardware elements and program code may be referred to as a particular type of circuitry.

The term “processor circuitry” or “processor” as used herein thus refers to, is part of, or includes circuitry capable of sequentially and automatically carrying out a sequence of arithmetic or logical operations, or recording, storing, and/or transferring digital data. The term “processor circuitry” or “processor” may refer to one or more application processors, one or more baseband processors, a physical central processing unit (CPU), a single- or multi-core processor, and/or any other device capable of executing or otherwise operating computer-executable instructions, such as program code, software modules, and/or functional processes.

Various embodiments may include fabrication techniques and methods of fabricating the above structures, devices, and systems. The embodiments described may be implemented by different means for implementing the functionality described above, and/or using instructions on a machine readable medium (such as a non-transitory machine readable medium).

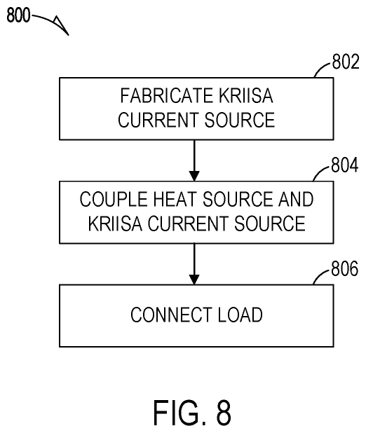

FIG. 8 illustrates a method of fabricating a Kriisa apparatus in accordance with some embodiments. FIG. 8 is only one example of such a method 800. Only some of the steps are show—other embodiments may have additional steps and/or the steps may be performed in a different order than that shown. As shown, at operation 802, the Kriisa current source may be fabricated. The manner of fabrication and materials used, as above, are provided in U.S. Pat. Nos. 8,053,942 and 8,581,469. At operation 804, a heat source may be coupled to the Kriisa current source. The heat source may be attached to the Kriisa current source or vice versa. The heat source, as above, may be any circuit (such as a processor) that generates heat and it may be desirable to provide cooling to maintain optimal functionality of the circuit. The heat source may be directed disposed on (in physical contact with) the Kriisa current source, for example. At operation 806, a load may be connected to the Kriisa current source. The load may be circuitry and may be the same as, or different from, the heat source. The heat source and the Kriisa current source may be fabricated on, or later attached to a substrate or other circuitry, such as a printed circuit board. In some embodiments, the heat source may be a chip and the Kriisa current source physically contacts the housing of the chip. After coupling the heat source and the Kriisa current source together, the system may be operated in the manner described above.

### EXAMPLES

Example 1 is an apparatus comprising: a substrate; and a Kriisa current source disposed on the substrate; and a heat source to which the Kriisa current source is thermally and electrically coupled to provide current to, and cooling of, the heat source.

In Example 2, the subject matter of Example 1 includes, wherein the Kriisa current source and the heat source are disposed on a same surface of the substrate.

In Example 3, the subject matter of Example 2 includes, wherein the Kriisa current source is disposed between the heat source and the substrate.

In Example 4, the subject matter of Examples 2-3 includes, wherein the heat source is disposed between the Kriisa current source and the substrate.

In Example 5, the subject matter of Examples 2-4 includes, another Kriisa current source, the heat source disposed between the Kriisa current source and the other Kriisa current source.

In Example 6, the subject matter of Examples 1-5 includes, wherein the Kriisa current source and the heat source are disposed on different surfaces of the substrate.

In Example 7, the subject matter of Examples 1-6 includes, wherein the heat source is an integrated circuit fabricated on the substrate.

In Example 8, the subject matter of Example 7 includes, wherein the Kriisa current source and the integrated circuit are disposed on a same surface of the substrate.

In Example 9, the subject matter of Example 8 includes, another Kriisa current source disposed on a different surface of the substrate as the integrated circuit.

In Example 10, the subject matter of Examples 8-9 includes, another Kriisa current source, the integrated circuit disposed between the Kriisa current source and the other Kriisa current source.

In Example 11, the subject matter of Examples 7-10 includes, wherein the Kriisa current source and the integrated circuit are disposed on different surfaces of the substrate.

Example 12 is a system comprising: an electronic apparatus that includes: a substrate on which an integrated circuit is disposed; and a Kriisa current source disposed on the substrate, the Kriisa current source thermally and electrically coupled to the integrated circuit to provide cooling of the integrated circuit; a temperature sensor configured to detect a temperature of the integrated circuit; and a temperature controller configured to control cooling provided by the Kriisa current source to limit a range of temperatures of the integrated circuit.

In Example 13, the subject matter of Example 12 includes, wherein the Kriisa current source and the integrated circuit are disposed on a same surface of the substrate.

In Example 14, the subject matter of Example 13 includes, another Kriisa current source disposed on a different surface of the substrate as the integrated circuit.

In Example 15, the subject matter of Examples 13-14 includes, another Kriisa current source, the integrated circuit disposed between the Kriisa current source and the other Kriisa current source.

In Example 16, the subject matter of Examples 12-15 includes, wherein the Kriisa current source and the integrated circuit are disposed on different surfaces of the substrate.

In Example 17, the subject matter of Examples 12-16 includes, wherein the Kriisa current source provides current to the integrated circuit as a function of (proportional to), and simultaneously with, cooling the integrated circuit.

In Example 18, the subject matter of Examples 12-17 includes, wherein the Kriisa current source provides current to a load, coupled to the Kriisa current source via leads, as a function of, and simultaneously with, cooling the integrated circuit.

In Example 19, the subject matter of Examples 12-18 includes, wherein the temperature controller is controlled by user inputs remote from the electronic apparatus.

Example 20 is a method of fabricating a circuit, the method comprising: forming comprising an integrated circuit comprising a plurality of semiconductor and insulating layers on a substrate; and forming a Kriisa current source on the substrate coupled to the integrated circuit to simultaneously provide current to, and cooling of, the integrated circuit.

In Example 21, the subject matter of Example 20 includes, wherein the Kriisa current source and the integrated circuit are formed on a same surface of the substrate.

In Example 22, the subject matter of Example 21 includes, forming another Kriisa current source on a different surface of the substrate as the integrated circuit.

In Example 23, the subject matter of Examples 20-22 includes, forming the Kriisa current source and the integrated circuit on different surfaces of the substrate.

Example 24 is at least one machine-readable medium including instructions that, when executed by processing circuitry, cause the processing circuitry to perform operations to implement of any of Examples 1-23.

Example 25 is an apparatus comprising means to implement of any of Examples 1-23.

Example 26 is a system to implement of any of Examples 1-23.

Example 27 is a method to implement of any of Examples 1-23.

Although an embodiment has been described with reference to specific example embodiments, it will be evident that various modifications and changes may be made to these embodiments without departing from the broader scope of the present disclosure. Accordingly, the specification and drawings are to be regarded in an illustrative rather than a restrictive sense. The accompanying drawings that form a part hereof show, by way of illustration, and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

The subject matter may be referred to herein, individually and/or collectively, by the term “embodiment” merely for convenience and without intending to voluntarily limit the scope of this application to any single inventive concept if more than one is in fact disclosed. Thus, although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, UE, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. An apparatus comprising:
a Kriisa current source;
a heat source to which the Kriisa current source is thermally and electrically coupled to provide current to, and cooling of, the heat source; and
a substrate on which the heat source and the Kriisa current source are disposed.

2. The apparatus of claim 1, wherein the Kriisa current source and the heat source are disposed on a same surface of the substrate.

3. The apparatus of claim 2, wherein the Kriisa current source is disposed between the heat source and the substrate.

4. The apparatus of claim 2, wherein the heat source is disposed between the Kriisa current source and the substrate.

5. The apparatus of claim 2, further comprising another Kriisa current source, the heat source disposed between the Kriisa current source and the other Kriisa current source.

6. The apparatus of claim 1, wherein the Kriisa current source and the heat source are disposed on different surfaces of the substrate.

7. The apparatus of claim 1, wherein the heat source is an integrated circuit fabricated on the substrate.

8. The apparatus of claim 7, wherein the Kriisa current source and the integrated circuit are disposed on a same surface of the substrate.

9. The apparatus of claim 8, further comprising another Kriisa current source disposed on a different surface of the substrate as the integrated circuit.

10. The apparatus of claim 8, further comprising another Kriisa current source, the integrated circuit disposed between the Kriisa current source and the other Kriisa current source.

11. The apparatus of claim 7, wherein the Kriisa current source and the integrated circuit are disposed on different surfaces of the substrate.

12. A system comprising:
an electronic apparatus that includes:
a substrate on which an integrated circuit is disposed; and
a Kriisa current source disposed on the substrate, the Kriisa current source thermally and electrically coupled to the integrated circuit to provide cooling of the integrated circuit;
a temperature sensor configured to detect a temperature of the integrated circuit; and
a temperature controller configured to control cooling provided by the Kriisa current source to limit a range of temperatures of the integrated circuit.

13. The system of claim 12, wherein the Kriisa current source and the integrated circuit are disposed on a same surface of the substrate.

14. The system of claim 13, further comprising another Kriisa current source disposed on a different surface of the substrate as the integrated circuit.

15. The system of claim 13, further comprising another Kriisa current source, the integrated circuit disposed between the Kriisa current source and the other Kriisa current source.

16. The system of claim 12, wherein the Kriisa current source and the integrated circuit are disposed on different surfaces of the substrate.

17. The system of claim 12, wherein the Kriisa current source provides current to the integrated circuit as a function of, and simultaneously with, cooling the integrated circuit.

18. The system of claim 12, wherein the Kriisa current source provides current to a load, coupled to the Kriisa current source via leads, as a function of, and simultaneously with, cooling the integrated circuit.

19. The system of claim 12, wherein the temperature controller is controlled by user inputs remote from the electronic apparatus.

20. A method of fabricating a circuit, the method comprising:
forming comprising an integrated circuit comprising a plurality of semiconductor and insulating layers on a substrate; and
forming a Kriisa current source on the substrate coupled to the integrated circuit to simultaneously provide current to, and cooling of, the integrated circuit.
